(19) United States
(12) Patent Application Publication
(10) Pub. No.: US 2026/0009846 A1
(43) Pub. Date: Jan. 8, 2026

(54) POWER TEST SYSTEM AND SYSTEM-ON-CHIP INCLUDING THE SAME

(71) Applicant: ITDA SEMICONDUCTOR CO., LTD., Hwaseong-si (KR)

(72) Inventors: Ahchan KIM, Hwaseong-si (KR); Hoyeon JEON, Seongnam-si (KR); Ingyu KIM, Hwaseong-si (KR); Jaesung LEE, Seoul (KR)

(73) Assignee: ITDA SEMICONDUCTOR CO., LTD., Hwaseong-si (KR)

(21) Appl. No.: 19/255,681

(22) Filed: Jun. 30, 2025

(30) Foreign Application Priority Data
Jul. 2, 2024 (KR) 10-2024-0086592
Sep. 5, 2024 (KR) 10-2024-0120771

(51) Int. Cl. G01R 31/317

(52) U.S. Cl. CPC G01R 31/31721

(57) ABSTRACT

A power test system capable of performing a power test on a power management interface in a test mode and a system-on-chip including the same. The power test system according to an embodiment of the present disclosure includes: a target power test controller that generates a target power test mode signal indicating whether a target is in a test mode and target power test data provided to the target while a target test mode is activated; and a target power controller that receives a pure test mode signal indicating whether the target is in a pure test mode, the target power test mode signal and the target power test data, transmits preset data to the target when the pure test mode is activated, and transmits the target power test data to the target when both the pure test mode and the target test mode are activated.

### CROSS-REFERENCE TO RELATED APPLICATION

This application claims the benefit of and priority to Korean Patent Application Nos. 10-2024-0086592, filed on Jul. 2, 2024, and 10-2024-0120771, filed on Sep. 5, 2024, the entire disclosures of which are incorporated herein by reference in their entirety.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### TECHNICAL FIELD

The present disclosure relates to a power test system and a system-on-chip including the same, and more specifically, to a power test system capable of performing a power test on a power management interface in a test mode and a system-on-chip including the same.

### BACKGROUND

A system-on-chip (SoC) refers to a technology that integrates various functional blocks such as a central processing unit (CPU), a memory, an interface, a digital signal processing circuit, and an analog signal processing circuit into a single semiconductor integrated circuit to implement a computer system or other electronic system, or an integrated circuit (IC) integrated according to the technology. The SoC has evolved into more complex systems including various functional blocks such as processors, multimedia, graphics, interfaces, and security. The SoC may be driven in a test mode to detect defects during the design and manufacturing process and to verify that the SoC operates properly, and may be driven in a functional mode when passing a test and operating normally.

FIG. 1 is a block diagram illustrating a typical system-on-chip (SoC) device.

The SoC device may include an input/output pad 110, a clock management unit (CMU) 120, a power management unit (PMU) 130, a reset management unit (RMU) 140, and one or more intellectual property (IP) blocks 150, 160. When the SoC device operates in a functional mode, the CMU 120 may generate first and second functional clocks (CLK1, CLK2) to be provided to each of the first and second IP blocks 150, 160.

Each of the first and second IP blocks 150, 160 is connected to a system bus and may communicate with each other through the system bus. Each of the first and second IP blocks 150, 160 may be a processor, a graphic processor, a memory controller, and an input and output interface block.

The CMU 120 includes a plurality of clock components, wherein a first functional clock (CLK1) may be provided to the first IP block 150 when the first IP block 150 operates, and a second functional clock (CLK2) may be provided to the second IP block 160 when the second IP block 160 operates.

The PMU 130 includes a plurality of power components and controls power supplied to the SoC device. For example, when the SoC device enters a standby mode, the PMU 130 provides a power sequence (PWR1, PWR2) for powering down the first and second IP blocks 150, 160 so that power supplied to the IP blocks is cut off. In addition, when the SoC device operates in a driving mode, the PMU 130 provides a power sequence (PWR1, PWR2) for powering up the first and second IP blocks 150, 160 so that power is supplied to each IP block.

The RMU 140 detects a reset mode of the SoC device and transmits a reset signal (RST1, RST2) to the first and second IP blocks 150, 160 through the PMU 130 so that the hardware may be initialized. In addition, the reset signal generated from the RMU 140 may also be transmitted to the PMU 130 and the CMU 120, so that when the IP block 150, 160 is reset, the power components of the PMU 130 and the clock components of the CMU 120 may also be reset.

A pure test may be performed to functionally verify and detect defects of the digital circuits configuring the SoC. The pure test is a process of verifying the logic path and state of a digital circuit, and may include a scan test, a built-in self-test (BIST), a pattern-based test, and a reset test.

In general, in the test mode for testing IP blocks, the power management unit only supplies power to the IP block all the time to perform tests on the IP block, and no power test is performed on the power management unit.

### SUMMARY

An aspect of the present disclosure is directed to providing a power test system capable of performing a power test to check whether a power management interface that configures a power management unit operates normally in a test mode and a system-on-chip including the same.

The power test system according to an embodiment of the present disclosure includes: a target power test controller that generates a target power test mode signal (TEST_MODE) indicating whether a target is in a test mode and target power test data (TEST_MODE_DATA) provided to the target while a target test mode is activated; and a target power controller that receives a pure test mode signal (PURE_TEST_MODE) indicating whether the target is in a pure test mode, the target power test mode signal (TEST_MODE) and the target power test data (TEST_MODE_DATA), transmits preset data (PRESET_DATA) to the target when the pure test mode is activated, and transmits the target power test data (TEST_MODE_DATA) to the target when both the pure test mode and the target test mode are activated.

Preferably, the target power controller transmits a power control signal (DATA) provided from a power component to the target when the pure test mode is deactivated.

Preferably, the target power test controller is a controller based on a built-in IEEE1687 standard.

Preferably, the target is at least one of an isolation interface component, a switch control interface component, a retention interface component, an automatic power management interface component, a reference clock gating interface component, a handshake interface component, or a user-defined interface component.

Preferably, the target power test controller includes a test mode test data register (TDR) that outputs a target power test mode signal (TEST_MODE) indicating whether a power test mode of the target is activated or deactivated, and a test control TDR that outputs the target power test data (TEST_MODE_DATA) when the target is activated in the power test mode.

More preferably, the test mode TDR and the test control TDR are set via an internal joint test action group (IJTAG) interface.

More preferably, the target power controller includes: a first test multiplexer which receives the power control signal (DATA) and the preset data (PRESET_DATA) as input terminals and the pure test mode signal (PURE_TEST_MODE) as a selection terminal and selects and outputs between the power control signal (DATA) and the preset data (PRESET_DATA) depending on whether the pure test mode is activated; and a second test multiplexer which receives an output of the first test multiplexer and the target power test data (TEST_MODE_DATA) as input terminals and the target power test mode signal (TEST_MODE) as a selection terminal and selects and outputs between the output of the first test multiplexer and the target power test data (TEST_MODE_DATA) depending on whether the target power test mode is activated.

More preferably, the preset data is a value that needs to be provided to the target in the pure test mode.

The system-on-chip according to an embodiment of the present disclosure includes a power test system, wherein the power test system according to an embodiment of the present disclosure includes: a target power test controller that generates a target power test mode signal (TEST_MODE) indicating whether a target is in a test mode and target power test data (TEST_MODE_DATA) provided to the target while a target test mode is activated; and a target power controller that receives a pure test mode signal (PURE_TEST_MODE) indicating whether a target is in a pure test mode, the target power test mode signal (TEST_MODE) and the target power test data (TEST_MODE_DATA), transmits preset data (PRESET_DATA) to the target when the pure test mode is activated, and transmits the target power test data (TEST_MODE_DATA) to the target when both the pure test mode and the target test mode are activated.

Preferably, the target power controller transmits a power control signal (DATA) provided from a power component to the target when the pure test mode is deactivated.

Preferably, the target power test controller is a controller based on a built-in IEEE1687 standard.

Preferably, the target is at least one of an isolation interface component, a switch control interface component, a retention interface component, an automatic power management interface component, a reference clock gating interface component, a handshake interface component, or a user-defined interface component.

Preferably, the target power test controller includes a test mode test data register (TDR) that outputs a target power test mode signal (TEST_MODE) indicating whether a power test mode of the target is activated or deactivated, and a test control TDR that outputs the target power test data (TEST_MODE_DATA) when the target is activated in the power test mode.

More preferably, the test mode TDR and the test control TDR are set via an internal joint test action group (IJTAG) interface.

Preferably, the target power controller includes: a first test multiplexer which receives the power control signal (DATA) and the preset data (PRESET_DATA) as input terminals and the pure test mode signal (PURE_TEST_MODE) as a selection terminal and selects and outputs between the power control signal (DATA) and the preset data (PRESET_DATA) depending on whether the pure test mode is activated; and a second test multiplexer which receives an output of the first test multiplexer and the target power test data (TEST_MODE_DATA) as input terminals and the target power test mode signal (TEST_MODE) as a selection terminal and selects and outputs between the output of the first test multiplexer and the target power test data (TEST_MODE_DATA) depending on whether the target power test mode is activated.

More preferably, the preset data is a value that needs to be provided to the target in the pure test mode.

### Advantageous Effects

According to the present disclosure, the following effects can be achieved.

An embodiment of the present disclosure can test whether a power management interface and power interface components operate normally when a system-on-chip device is driven in a test mode, thereby expanding test coverage.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings described below, in which similar reference numerals indicate similar elements, but the embodiments are not limited thereto.

FIG. 1 is a block diagram illustrating a general block diagram of a system-on-chip (SoC) device.

FIG. 2 is a configuration diagram illustrating a system-on-chip device including a power management cluster to which an embodiment of the present disclosure is applied.

FIG. 3 is a detailed configuration diagram illustrating a domain power manager (PMD) and a power management interface (PMIF) of FIG. 2.

FIG. 4 is a configuration block diagram illustrating a power test system according to an embodiment of the present disclosure.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the embodiments disclosed below but may be implemented in various different forms, and the present embodiments are merely provided to fully disclose the scope of the invention to those skilled in the art.

Unless otherwise defined, all terms (including technical and scientific terms) used herein have the same meaning as commonly understood by those skilled in the technical field to which the present disclosure pertains. It will be further understood that terms, such as those defined in commonly used dictionaries, should not be interpreted in an idealized or overly formal sense unless expressly so defined herein.

For example, the term “technique” may refer to a system, method, computer readable instruction, module, algorithm, hardware logic, and/or operation as permitted by the context described above and throughout a document.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it intends to mean that the portion may additionally include another component, rather than excluding the same, unless specified to the contrary.

In this present disclosure, the terms “comprising,” “having,” or the like are used to specify that features, steps, operations, elements and/or components exist, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

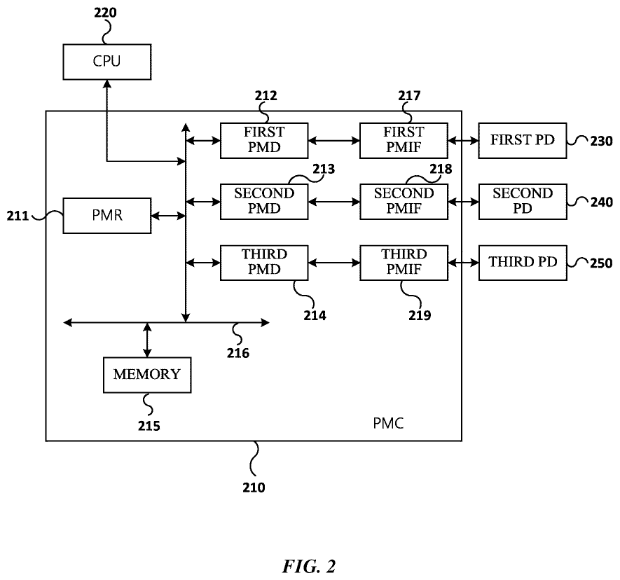

FIG. 2 is a configuration diagram illustrating a system-on-chip device including a power management cluster to which an embodiment of the present disclosure is applied. The system-on-chip device refers to a product and system that are fully implemented within a single integrated circuit, and may be implemented as a chip, a module, or a system.

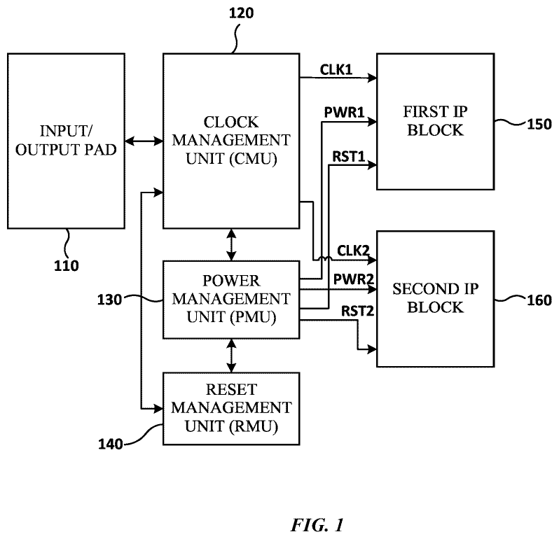

The system-on-chip device may include a power management cluster (PMC) 210, a central processing unit (CPU) 220 that controls the power management cluster 210 via software, and at least one power domain (PD) 230, 240, 250. The power domains 230, 240, and 250 may be IP blocks shown in FIG. 1. The CPU 220 controls the power management cluster 210 and may be one of the power domains that constitute the system-on-chip device. The power management cluster 210 may be included in the power management unit 130 of FIG. 1.

The power management cluster 210 may provide a power-up/power-down sequence corresponding to each of the at least one power domain 230, 240, 250. Each power domain 230, 240, 250 may process the power-up/power-down sequence to enter a power-up state or a power-down state. The system-on-chip device may include at least one power management cluster 210.

The PD 230, 240, 250 may include a core domain including the CPU 220, a memory domain including a memory subsystem such as a main memory or a cache memory, a graphics and video domain including multimedia elements such as a graphics processing unit or a video encoding/decoding unit, and an input/output domain including input/output interface elements for communication with the outside. Each power domain may include lower sub-power domains.

The power management cluster 210 corresponds to each of the power domains 230, 240, 250 and may include: at least one domain power manager (PMD; Power Management for Domain) 212, 213, 214 for controlling the power of the corresponding power domain; a root power manager (PMR; Power Management for Root) 211 for managing the at least one PMD; a memory 215 for storing a program that operates the PMR 211 and the PMDs; and at least one power management interface (PMIF; Power Management Interface) 217, 218, 219 disposed between the PMDs and the power domains 230, 240, 250.

The PMR 211, the PMD 212, 213, 214 and the memory 215 are disposed in an always-on (AON) area; and the corresponding PMD 212, 213, 214 and the power management interfaces 217, 218, 219 are connected by a P-link; and the PMIFs 217, 218, 219 may be disposed on the side of each PD 230, 240, 250.

The at least one PMD 212, 213, 214, the PMR 211 and the memory 215 may be interconnected by an internal bus 216. The program stored in the memory 215 may include instructions and data.

The PMR 211 may receive a system power up/down command from the CPU 220. The PMR 211 may perform booting of the system-on-chip device by operating at least one PMD 212, 213, 214 based on a ROM sequence (instructions and data for performing booting) at the time of booting. In addition, when a system power up/down command is received from the CPU 220, the at least one PMD 212, 213, 214 is operated based on a RAM sequence (instructions and data for performing a command) to perform power on/off of the system-on-chip device or a subsystem including a plurality of power domains.

The at least one PMD 212, 213, 214 may perform power up/down sequence control on a corresponding power domain based on the RAM sequence (instructions and data for performing the command) when a domain power up/down command for power control of a power domain is received from the CPU 220.

The first PMD 212 may output a power control signal to the first PD 230 and perform a power up/down sequence, the second PMD 213 may output a power control signal to the second PD 240 and perform a power up/down sequence, and the third PMD 214 may output a power control signal to the third PD 250 and perform a power up/down sequence. In other words, since power control of each power domain 230, 240, 250 may be performed in parallel by matching a separate PMD 212, 213, 214 to each PD 230, 240, 250, efficient and fast processing is possible.

The memory 215 may store instructions and data as binary code for the PMR 211 to perform a system power up/down command, and for each PMD 212, 213, 214 to perform a domain power up/down command. The memory 215 may include a ROM and a RAM.

In FIG. 2, an example of a system-on-chip device including three power domains and three domain power managers is illustrated; however, the number of power domains may vary depending on the complexity of the system-on-chip device, and the number of domain power managers may vary accordingly.

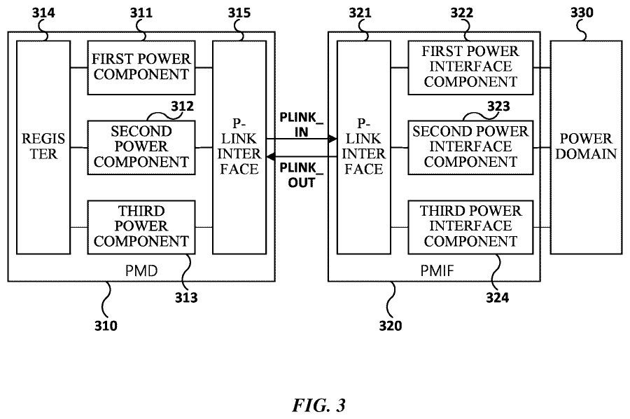

FIG. 3 is a detailed configuration diagram illustrating a domain power manager (PMD) and a power management interface (PMIF) shown in FIG. 2.

The PMD 310 may transmit power control signals to a power domain 330 through a PMIF 320 and perform a power-up or power-down sequence of the power domain 330. As a result, the power domain 330 may transition from a power-up state to a power-down state or from a power-down state to a power-up state. The power control signals for performing the power-up or power-down sequence may include reset signals (Reset), isolation signals (Isolation), switch control signals (Switch Control), and retention signals (Retention). These power control signals may be added, removed, or modified according to the specifications of the power domain 330, and may each correspond to a power component 311, 312, 313 of the PMD 310.

The PMD 310 may include a plurality of power components 311, 312, 313 for transmitting and receiving power control signals to and from the power domain 330, a register 314 for controlling each of the power components 311, 312, 313, and a P-link interface 315 for interfacing the power components with the PMIF 320.

The PMIF 320 may include a P-link interface 321 for interfacing with the PMD 310, and a plurality of power interface components 322, 323, 324, each of which corresponds to one of the power components 311, 312, 313 and interfaces between the corresponding power component and the power domain 330.

In FIG. 3, the PMD 310 is exemplified as including three power components 311, 312, 313, and the PMIF 320 is exemplified as including three power interface components 322, 323, 324; however, the number of power components and power interface components may be designed to vary depending on the function of the PMD.

The power components 311, 312, 313 may include at least one of: a reset component for transmitting a reset signal to the power domain; an isolation component for transmitting an isolation signal to the power domain; a switch control component for transmitting a switch control signal to the power domain; a retention component for transmitting a retention signal to the power domain; an automatic power manager component for automatically performing power up/down based on a hardware trigger signal; a reference clock gating component for gating a reference clock supplied to the power domain; a handshake component for generating a handshake control signal with the power domain; a clock link component for generating a link control signal with a clock management unit; a P-channel handshake component for generating a P-channel handshake control signal with the power domain; a user-defined output component for generating a user-defined output signal within the power domain; and a user-defined input component for generating a user-defined input signal within the power domain.

The plurality of power interface components 322, 323, 324 may include: a reset interface component corresponding to the reset component and interfacing between the reset component and the power domain; an isolation interface component corresponding to the isolation component and interfacing between the isolation component and the power domain; a switch control interface component corresponding to the switch control component and interfacing between the switch control component and the power domain; a retention interface component corresponding to the retention component and interfacing between the retention component and the power domain; an automatic power management interface component corresponding to the automatic power management component and interfacing between the automatic power management component and the power domain; a reference clock gating interface component corresponding to the reference clock gating component and interfacing between the reference clock gating component and the power domain; a handshake interface component corresponding to the handshake component and interfacing between the handshake component and the power domain; a P-channel handshake interface component corresponding to the P-channel handshake component and interfacing between the P-channel handshake component and the power domain; a user-defined interface component corresponding to the user-defined component and interfacing between the user-defined component and the power domain; and a user-defined input interface component corresponding to the user-defined input component and interfacing between the user-defined input component and the power domain.

The domain power manager 310 and the power management interface 320 are connected by a P-link interface 315, 321, signals transmitted from the domain power manager 310 to the power management interface 320 are transmitted to a P-link input (PLINK_IN), and signals transmitted from the power management interface 320 to the domain power manager 310 are transmitted to a P-link output (PLINK_OUT).

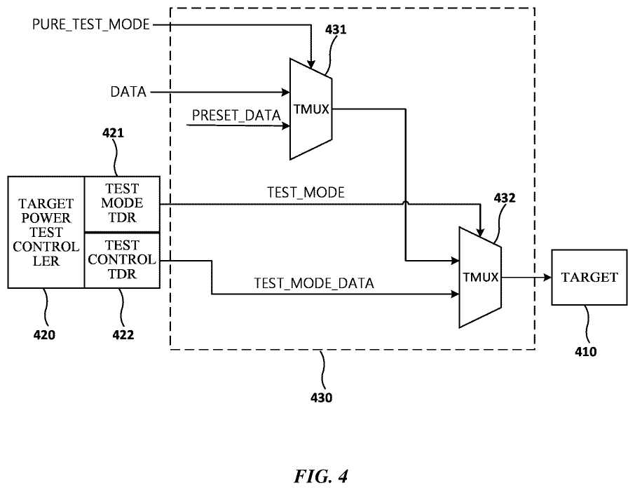

FIG. 4 is a configuration block diagram illustrating a power test system according to an embodiment of the present disclosure.

The power test system according to an embodiment of the present disclosure includes: a target power test controller 420 that generates a target power test mode signal (TEST_MODE) indicating whether a target 410 is in a test mode and target power test data (TEST_MODE_DATA) provided to the target 410 while a target test mode is activated; and a target power controller 430 that receives a pure test mode signal (PURE_TEST_MODE) indicating whether the target is in a pure test mode, the target power test mode signal (TEST_MODE) and the target power test data (TEST_MODE_DATA), transmits preset data (PRESET_DATA) to the target 410 when the pure test mode is activated, and transmits the target power test data (TEST_MODE_DATA) to the target 410 when both the pure test mode and the target test mode are activated.

The target power controller 410 transmits a power control signal (DATA) provided from a power component to the target 410 when the pure test mode is deactivated.

The target 410 may be a power interface component related to power control of a power domain. The target 410 may be at least one of an isolation interface component, a switch control interface component, a retention interface component, an automatic power management interface component, a reference clock gating interface component, a handshake interface component, or a user-defined interface component.

The pure test mode signal is the most global test mode signal that indicates that the system-on-chip is in a test mode rather than a functional mode. Various test modes such as a scan test, a built-in self-test (BIST) test, and a hard macro test may be performed, and the pure test mode signal becomes ‘high’ in all of these test modes.

In order to test the power domain in the pure test mode, active low data or active high data may need to be provided depending on the target 410. For example, when the target is the automatic power management interface, active low data may need to be provided, and when the target is the reference clock gating interface component, active high data may need to be provided. In the pure test mode, data to be provided to the target 410 may be set as the preset data (PRESET_DATA). The provision of the preset data to the target in the pure test mode is necessary to make the power control signal a specific value before selecting a test mode regardless of the type of test mode.

The target power controller 430 may include: a first test multiplexer 431 which receives a power control signal (DATA) and preset data (PRESET_DATA) as input terminals and a pure test mode signal (PURE_TEST_MODE) as a selection terminal and selects and outputs between the power control signal (DATA) and preset data (PRESET_DATA) depending on whether the pure test mode is activated; and a second test multiplexer 432 which receives an output of the first test multiplexer 431 and target power test data (TEST_MODE_DATA) as input terminals and the target power test mode signal (TEST_MODE) as a selection terminal and selects and outputs between the output of the first test multiplexer 431 and the target power test data (TEST_MODE_DATA) depending on whether the target power test mode is activated.

The target power test controller 420 may include a test mode test data register (TDR) 421 that outputs the target power test mode signal (TEST_MODE) indicating whether a power test mode of the target 410 is activated or deactivated, and a test control TDR 422 that outputs the target power test data (TEST_MODE_DATA) when the target 410 is activated in the power test mode.

The target power test controller 420 may be a controller based on a built-in IEEE1687 standard. The target power test controller 420 may set the test mode TDR 421 and the test control TDR 422 through an internal joint test action group (IJTAG) interface.

The test mode TDR 421 may be configured with a flip-flop and may output the target power test mode signal (TEST_MODE) indicating power test mode activation/deactivation of the target 410 to the target power controller 430. In other words, the target power test mode signal may be a 1-bit signal indicating power test mode activation/deactivation.

The test control TDR 422 may be configured with a flip-flop and may output the target power test data (TEST_MODE_DATA) to the target power controller 430. The target power test data (TEST_MODE_DATA) may be a value that determines whether to output active data or non-active data to the target when the target power test mode is activated. Accordingly, the target power test data (TEST_MODE_DATA) may be a 1-bit signal.

Hereinafter, the operation of the power test system according to an embodiment of the present disclosure will be described.

In the functional mode of the system-on-chip device, the pure test mode is deactivated and the pure test mode signal (PURE_TEST_MODE) becomes a non-active state. Then, the first test multiplexer 431 selects the power control signal DATA) among the power control signal (DATA) and the preset data (PRESET_DATA) and outputs the same. In this connection, since the target power test mode is also deactivated, the target power test mode signal (TEST_MODE) is in a non-active state, and the second test multiplexer 432 selects the output of the first test multiplexer 431 among the output of the first test multiplexer 431 and the target power test data (TEST_MODE_DATA), in other words, the power control signal (DATA) and transmits the same to the target 410.

When the pure test mode of the system-on-chip device is activated, the pure test mode signal (PURE_TEST_MODE) becomes active and the first test multiplexer 431 outputs the preset data (PRESET_DATA) among the power control signal (DATA) and the preset data (PRESET_DATA). The preset data (PRESET_DATA) may be set to a value (active high or active low) that needs to be provided to the target 410 in the pure test mode.

When the pure test mode is activated and the target power test mode is inactive, the target power test controller 420 outputs the target power test mode signal (TEST_MODE) in a non-active state. Then, the second test multiplexer 432 selects the output of the first test multiplexer 431 among the output of the first test multiplexer 431 and the target power test data (TEST_MODE_DATA), in other words, the preset data (PRESET_DATA) and outputs the same to the target 410. As a result, the data required for the target 410 may be supplied in the pure test mode.

When the pure test mode is activated and the target power test mode is activated, the target power test controller 420 outputs the target power test mode signal (TEST_MODE) in an active state, and the second test multiplexer 432 selects the target power test data (TEST_MODE_DATA) among the output of the first test multiplexer 431 and the target power test data (TEST_MODE_DATA) and outputs the same to the target 410. As a result, power testing for the target 410 in the target power test mode becomes possible.

It should be understood that many variations and modifications may be made to the above-described embodiments, and the element thereof is one of other permissible examples. All the modifications and variations are intended to be included in the scope of the present disclosure and protected by the following claims. The exemplary embodiment of the present disclosure described above may be implemented in the form of a program command which may be executed through various computer components to be recorded in a computer readable recording medium. The computer readable recording medium may include solely a program command, a data file, and a data structure or a combination thereof. The program commands recorded in the computer readable recording medium may be specifically designed or constructed for the present disclosure or known to those skilled in the art of a computer software to be used. Examples of the computer readable recording medium include magnetic media such as a hard disk, a floppy disk, or a magnetic tape, optical recording media such as a CD-ROM or a DVD, magneto-optical media such as a floptical disk, and a hardware device which is specifically configured to store and execute the program command such as a ROM, a RAM, and a flash memory. Examples of the program command include not only a machine language code which is generated by a compiler but also a high level language code which may be executed by a computer using an interpreter. The hardware device may operate as one or more software modules in order to perform the operation of the present disclosure and vice versa.

The specified matters and limited exemplary embodiments and drawings such as specific elements in the present disclosure have been disclosed for broader understanding of the present disclosure, but the present disclosure is not limited to the exemplary embodiments, and various modifications, additions and substitutions are possible from the disclosure by those skilled in the art.

Accordingly, the spirit of the present disclosure is defined by the appended claims rather than by the description preceding them, and all changes and modifications that fall within metes and bounds of the claims, or equivalents of such metes and bounds are therefore intended to be embraced by the range of the spirit of the present disclosure.

[Detailed Description of Main Elements]

| | |
|---|---|
| 410: target | 420: target power test controller |
| 421: test mode TDR | 422: test control TDR |
| 430: target power controller | 431: first test multiplexer |
| 432: second test multiplexer | |

What is claimed is:

1. A power test system comprising:
a target power test controller that generates a target power test mode signal (TEST_MODE) indicating whether a target is in a test mode and target power test data (TEST_MODE_DATA) provided to the target while a target test mode is activated; and
a target power controller that receives a pure test mode signal (PURE_TEST_MODE) indicating whether the target is in a pure test mode, the target power test mode signal (TEST_MODE) and the target power test data (TEST_MODE_DATA), transmits preset data (PRESET_DATA) to the target when the pure test mode is activated, and transmits the target power test data (TEST_MODE_DATA) to the target when both the pure test mode and the target test mode are activated.

2. The power test system of claim 1, wherein the target power controller transmits a power control signal (DATA) provided from a power component to the target when the pure test mode is deactivated.

3. The power test system of claim 1, wherein the target power test controller is a controller based on a built-in IEEE1687 standard.

4. The power test system of claim 1, wherein the target is at least one of an isolation interface component, a switch control interface component, a retention interface component, an automatic power management interface component, a reference clock gating interface component, a handshake interface component, or a user-defined interface component.

5. The power test system of claim 1, wherein the target power test controller comprises:
a test mode test data register (TDR) that outputs a target power test mode signal (TEST_MODE) indicating whether a power test mode of the target is activated or deactivated; and
a test control TDR that outputs the target power test data (TEST_MODE_DATA) when the target is activated in the power test mode.

6. The power test system of claim 5, wherein the test mode TDR and the test control TDR are set via an internal joint test action group (IJTAG) interface.

7. The power test system of claim 2, wherein the target power controller comprises:
a first test multiplexer which receives the power control signal (DATA) and the preset data (PRESET_DATA) as input terminals and the pure test mode signal (PURE_TEST_MODE) as a selection terminal and selects and outputs between the power control signal (DATA) and the preset data (PRESET_DATA) depending on whether the pure test mode is activated; and
a second test multiplexer which receives an output of the first test multiplexer and the target power test data (TEST_MODE_DATA) as input terminals and the target power test mode signal (TEST_MODE) as a selection terminal and selects and outputs between the output of the first test multiplexer and the target power test data (TEST_MODE_DATA) depending on whether the target power test mode is activated.

8. The power test system of claim 7, wherein the preset data is a value that needs to be provided to the target in the pure test mode.

9. A system-on-chip comprising a power test system, wherein the power test system comprises:
a target power test controller that generates a target power test mode signal (TEST_MODE) indicating whether a target is in a test mode and target power test data (TEST_MODE_DATA) provided to the target while a target test mode is activated; and
a target power controller that receives a pure test mode signal (PURE_TEST_MODE) indicating whether the target is in a pure test mode, the target power test mode signal (TEST_MODE) and the target power test data (TEST_MODE_DATA), transmits preset data (PRESET_DATA) to the target when the pure test mode is activated, and transmits the target power test data (TEST_MODE_DATA) to the target when both the pure test mode and the target test mode are activated.

10. The system-on-chip of claim 9, wherein the target power controller transmits a power control signal (DATA) provided from a power component to the target when the pure test mode is deactivated.

11. The system-on-chip of claim 9, wherein the target power test controller is a controller based on a built-in IEEE1687 standard.

12. The system-on-chip of claim 9, wherein the target is at least one of an isolation interface component, a switch control interface component, a retention interface component, an automatic power management interface component, a reference clock gating interface component, a handshake interface component, or a user-defined interface component.

13. The system-on-chip of claim 9, wherein the target power test controller comprises:
a test mode test data register (TDR) that outputs a target power test mode signal (TEST_MODE) indicating whether a power test mode of the target is activated or deactivated; and
a test control TDR that outputs the target power test data (TEST_MODE_DATA) when the target is activated in the power test mode.

14. The system-on-chip of claim 13, wherein the test mode TDR and the test control TDR are set via an internal joint test action group (IJTAG) interface.

15. The system-on-chip of claim 9, wherein the target power controller comprises:
a first test multiplexer which receives the power control signal (DATA) and the preset data (PRESET_DATA) as input terminals and the pure test mode signal (PURE_TEST_MODE) as a selection terminal and selects and outputs between the power control signal (DATA) and the preset data (PRESET_DATA) depending on whether the pure test mode is activated; and
a second test multiplexer which receives an output of the first test multiplexer and the target power test data (TEST_MODE_DATA) as input terminals and the target power test mode signal (TEST_MODE) as a selection terminal and selects and outputs between the output of the first test multiplexer and the target power test data (TEST_MODE_DATA) depending on whether the target power test mode is activated.

16. The system-on-chip of claim 15, wherein the preset data is a value that needs to be provided to the target in the pure test mode.
